(19) United States
(12) Patent Application Publication
(10) Pub. No.: US 2013/0059434 A1
(43) Pub. Date: Mar. 7, 2013

(54) METHOD FOR MANUFACTURING ELECTRODES AND WIRES IN GATE LAST PROCESS

(71) Applicants: Tao Yang, Beijing (CN); Chao Zhao, Kessel-Lo (BE); Junfeng Li, Beijing (CN); Jiang Yan, Newburgh, NY (US); Xiaobin He, Beijing (CN); Yihong Lu, Beijing (CN)

(72) Inventors: Tao Yang, Beijing (CN); Chao Zhao, Kessel-Lo (BE); Junfeng Li, Beijing (CN); Jiang Yan, Newburgh, NY (US); Xiaobin He, Beijing (CN); Yihong Lu, Beijing (CN)

(21) Appl. No.: 13/509,722

(22) PCT Filed: Nov. 29, 2011
(86) PCT No.: PCT/CN11/01991

§ 371 Date: May 14, 2012

(30) Foreign Application Priority Data
Sep. 7, 2011 (CN) 201110263768.4

(51) Int. Cl. H01L 21/28

(52) U.S. Cl. 438/586; 257/E21.19

(57) ABSTRACT

The present invention provides a method for manufacturing a gate electrode and a contact wire simultaneously in a gate last process, comprising the steps of: forming a gate trench in an inter layer dielectric layer on a substrate; forming a filling layer in the gate trench and on the inter layer dielectric layer; etching the filling layer and the inter layer dielectric layer to expose the substrate, to thereby form a source/drain contact hole; removing the filling layer to expose the gate trench and the source/drain contact hole; forming metal silicide in the source/drain contact hole; depositing a gate dielectric layer and a metal gate in the gate trench; filling metal in the gate trench and the source/drain contact hole; and planarizing the filled metal. In accordance with the manufacturing method of the present invention, the gate electrode wire will be made of the same metal material as the contact hole such that the two can be manufactured by one CMP process. Such a design has the advantages of simplifying complexity of process integration on one hand and greatly strengthening control of defects by CMP process on the other hand, thereby avoiding the defects like erosion and dishing that may be produced between different metal materials.

### CROSS REFERENCE

This application is a National Stage Application of, and claims priority to, PCT Application No. PCT/CN2011/001991, filed on Nov. 29, 2011, entitled “method for manufacturing electrodes and wires in gate last process”, which claims priority to Chinese Application No. 201110263768.4 filed on Sep. 7, 2011. Both the PCT application and the Chinese application are incorporated herein by reference in their entireties.

### FIELD OF THE INVENTION

The present invention relates to a method for manufacturing a semiconductor device, and more particularly to a method for manufacturing a gate electrode and a contact wire in a gate last process.

### BACKGROUND OF THE INVENTION

With the successful application of high-k/metal gate engineering to 45 nm technology node, it becomes an indispensable key modulation project for technology nodes less than sub-30 nm. For now, only Intel Corporation who adheres to a high-k/metal gate last process achieves success in mass production for 45 nm and 32 nm. In recent years, industry giants such as Samsung, TSMC, and Infineon who follow IBM Industry Alliance also shift the development emphasis from the previous high-k/metal gate first to gate last engineering.

In the current gate last engineering, a second generation sub-technique has been developed, wherein one of the differences between the processes lies in the preparation of contact holes and W plugs. The schematic diagrams for the two generations of techniques are provided in FIG. 1: as shown in FIG. 1A, in the first generation technique, the preparation of contact holes and W plugs are similar to those in 65 nm technique, that is, after forming the aluminum metal gates 1, completely isolating the device with silicon oxide 2, then performing chemical mechanical planarization, finally opening contact holes and forming the W plugs 3; in the second generation technique, the contact holes and W pugs 3 are directly prepared in the isolating layer of silicon oxide 2 between devices after performing chemical mechanical planarization to the gate electrodes 1 made of aluminum. Thus, with respect to the conventional W-CMP in the first generation technique, at this step, only CMP is needed to remove excess W; in the second generation technique, instead, W—Al buffer CMP is needed, in which process, in addition to grinding excess W, the gate electrode of Al will be inevitably grinded again at the end of W-CMP.

As for the gate last technique of the second generation technique, the processes of opening contact holes and forming W plugs are performed after the CMP of the metal gate electrode: etching through-holes for contacting above source/drain regions, filling metal W into the through-holes by CVD, then removing excess W by CMP process to form W plugs. Said CMP process brings lots of challenges to the CMP technology. Particularly said CMP process encounters two different metal materials W and Al, and since the two metal materials have different chemical erosion potentials, different hardness and different elasticity, said CMP process faces a big challenge about how to effectively control defects such as metal erosion between different metals and material dishing; besides, in terms of process integration, the difference in the materials of W plugs and metal gates also greatly increase the complexity of process integration, and at least two metal CMP processes are needed to obtain the desired structure.

In summary, gate electrodes and source/drain contact wires in the current gate last process are manufactured separately, process complexity is increased, CMP uniformity and process defects can not be easily controlled, and device defects possibly exists.

### SUMMARY OF THE INVENTION

Accordingly, the object of the present invention is to provide a method for manufacturing a gate electrode and a contact wire simultaneously in a gate last process, which simplifies complexity of process integration on one hand and greatly strengthens control of defects by CMP process on the other hand, thereby avoiding the defects like erosion and dishing that may be produced between different metal materials.

The present invention provides a method for manufacturing a gate electrode and a contact wire in a gate last process, comprising the steps of: forming a gate trench in an inter layer dielectric layer on a substrate; forming a filling layer in the gate trench and on the inter layer dielectric layer; etching the filling layer and the inter layer dielectric layer to expose the substrate, to thereby form a source/drain contact hole; removing the filling layer to expose the gate trench and the source/drain contact hole; forming metal silicide in the source/drain contact hole; depositing a gate dielectric layer and a metal gate in the gate trench; filling metal in the gate trench and the source/drain contact hole; and planarizing the filled metal.

Wherein the step of forming a gate trench comprises forming a dummy gate on the substrate, forming a spacer around the dummy gate, forming an inter layer dielectric layer on the dummy gate and the spacer, and CMP planarizing the inter layer dielectric layer to expose the dummy gate and removing the dummy gate.

Wherein further comprising forming a hardmask layer on the filling layer after the filling layer is formed. Wherein the hardmask layer is a low temperature oxide.

Wherein the filling layer has a thickness greater than the depth of the gate trench.

Wherein the filling layer is formed by spinning a plurality of times to avoid voids.

Wherein the filling layer is made of material with mobility and etching rate similar to that of the inter layer dielectric layer.

Wherein the filling layer is an anti-reflective coating.

Wherein the step of filling metal comprises filling an adhesive layer, a barrier layer, and a metal layer, sequentially, the adhesive layer comprising Ti, Ta, or TiN, TaN, the barrier layer comprising TiN, TaN or Ti, Ta, and the metal layer comprising W, Al, Cu, Ti, Ta and the combinations thereof.

Wherein the step of forming metal silicide comprises: forming a photoresist pattern to expose only the source/drain contact hole, depositing a metal precursor in the source/drain contact hole, annealing to cause the metal precursor to react with silicon in the substrate to produce the metal silicide, and removing the photoresist pattern. Wherein, the metal precursor comprises Ni, Pt, Co and the alloy thereof. Wherein, annealing is performed for 30 seconds at 400° C.

Wherein, the gate dialectic layer comprises silicon oxide, silicon oxynitride, or a high-k material, and the metal gate comprises Ti, Ta, TiN, or TaN.

In accordance with the method for manufacturing a gate electrode and a contact wire simultaneously in a gate last process of the present invention, the gate electrode wire is made of the same metal material as the contact hole, for example, the filling metals being W, and the metal gate electrode wire and the W plug wire can be manufactured by a single CMP process. Such a design has the advantages of simplifying complexity of process integration on one hand and greatly strengthening control of defects by CMP process on the other hand, thereby avoiding the defects like erosion and dishing that may be produced between different metal materials.

The objects of the invention as well as other objects not listed herein are satisfied within a range of the independent claims of the present invention. The embodiments of the present invention are defined in the independent claims and the specific features are defined in the dependent claims.

### BRIEF DESCRIPTION OF THE DRAWINGS

The technical solutions of the present invention are illustrated in detail with reference to the drawings, wherein

FIGS. 1A and 1B illustrate diagrammatic cross-sections for two generations of gate last processes in the prior art; and

FIGS. 2 to 12 illustrate diagrammatic cross-sections of the steps of the manufacturing method according to the present invention.

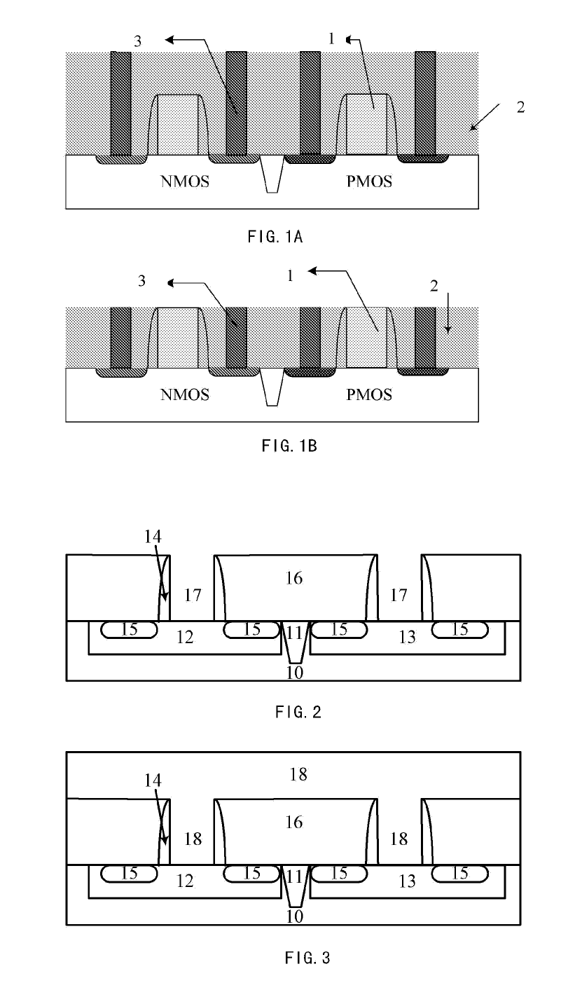

### DETAILED DESCRIPTION OF THE EMBODIMENTS

The features of the technical solutions and their technical effects of the present invention are described in detail with reference to the drawings in combination with the illustrative embodiments, and a method for manufacturing a gate electrode and a contact wire simultaneously in a gate last process is disclosed. It shall be pointed out that like reference signs indicate like structures.

First, referring to FIG. 2, a known gate last process is used to form a basic structure including gate trenches. An NMOS well region 12 and a PMOS well region 13 are formed respectively by well region ion implantation into a substrate 10 including an isolator 11. Then a pad layer and a dummy gate material layer (not shown) are deposited in turn on the well regions and etched to form a dummy gate stack structure. Next spacers 14 are formed by depositing and etching on the dummy gate stack structure. Source/drain regions 15 are formed by source/drain ion implantation with the spacers as a mask (the types for the implanted ions are different in NMOS and PMOS). An inter layer dielectric (ILD) 16 is deposited on the entire device and planarized to expose the dummy gates. Subsequently the dummy gates are etched and removed to form gate trenches. Wherein according to the requirement of electrical properties of the device, the substrate 10 may be mad of a substrate material, e.g., including monocrystalline silicon, silicon on insulator (SOI), monocrystalline germanium and germanium on insulator (GeOI), or other compound semiconductor material such as SiGe, SiC, InSb, GaAs, or GaN. The isolator 11 may be, e.g., field oxide isolation or shallow trench isolation (STI) and may be made of, e.g., a material of oxide or oxynitride. The pad layer may be made of, e.g., silicon oxide, silicon oxynitride, or other high-k material and may either be removed in a subsequent process or be remained as a gate dielectric layer. A material with different etching selectivity from the spacers 14 and ILD 16 is used for the dummy gate material layer, such as polycrystalline silicon, amorphous silicon, or microcrystalline silicon. The spacers 14 may be made of, e.g., silicon nitride, and ILD 16 may be made of, e.g., silicon oxide or silicon oxynitride. The dummy material layer may be removed by wet etching with NH₄OH or TMAH, while the pad layer may either be removed or be remained. When the pad layer is removed, it only functions as a substrate protection layer and etching stop layer. The pad layer also functions as a subsequent gate dielectric layer if it is made of a high-k material and the like. The formed gate trenches 17 may have a depth of, e.g., about 500-2000 Å, preferably 1000 Å.

Second, referring to FIG. 3, a filling layer 18 is formed in the gate trenches 17 and on the ILD 16 to fill the trenches 17 fully and keep a certain thickness from its upper surface, that is, the filling layer 18 has a thickness greater than the depth of the trenches 17. The filling layer 18 has good mobility to fill the trenches 17 fully and to has dry etching rate similar to that of the material of ILD 16, e.g., being organics such as bottom anti-reflective coating (BARC) and (top) anti-reflective coating (ARC), made of a material including but not limited to polyamide resin, phenolic resin or acryl resin and the like. According to process requirement, the filling layer 18 has no void. To ensure filling effect, preferably, spinning is performed several times. For example, filling is performed two times, 1000 Åfor each, such that the total thickness is 2000 Å. Next, drying and curing processes are performed after spinning the filling layer 18. Wherein the so-called filling layer 18 having etching rate “similar” to ILD 16 indicates that etching rates for them are the same or substantially the same (the difference between them is less than or equal to 5%).

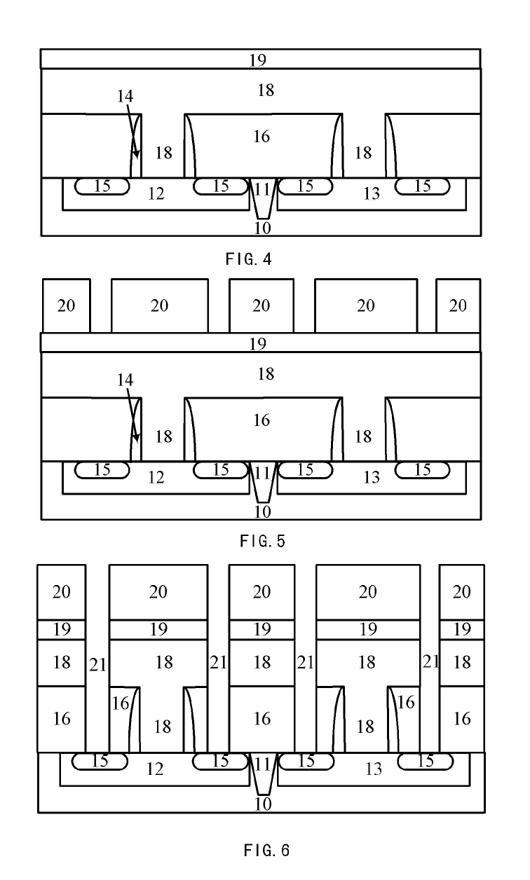

Then, referring to FIG. 4, a hard mask layer 19 is formed on the filling layer 18. For example, the hard mask layer 19, which can be low temperature oxide (LTO, silicon oxide formed mainly by a low temperature CVD process), is deposited on the filling layer 18 by conventional CVD process such as LPCVD or PECVD, to be used as a hard mask for etching contact holes later. The hard mask layer 19 may have a thickness of about 500 Å.

Next, referring to FIG. 5, a photo resist pattern 20 is formed on the hard mask layer 19. Photo resist (PR) is spin, exposed by a contact hole reticle and developed. Finally a pattern for the contact holes to be etched is formed.

Afterwards, referring to FIG. 6, source/drain contact holes 21 are formed by dry etching. The dry etching may include two steps: at a first step, the exposed hard mask layer 19 is etched to expose the filling layer 18; at a second step, the filling layer 18 and the ILD layer 16 are etched downward. Since the filling layer 18 and the ILD layer 16 have similar etching rates, the shape of the etched pattern for the filling layer 18 and the ILD layer 16 below the hard mask layer 19 will not be affected by different etching speeds. The second step of etching will stop on the surface of the source/drain regions 15, to finally manufacture contact holes 21 on the ILD 16. After etching, the wafer is washed and dried, to remove etching residuals completely. In FIG. 6, spacers 14 will undergo any change no longer in subsequent processes, so the reference sign of spacers 14 is omitted in the following figures.

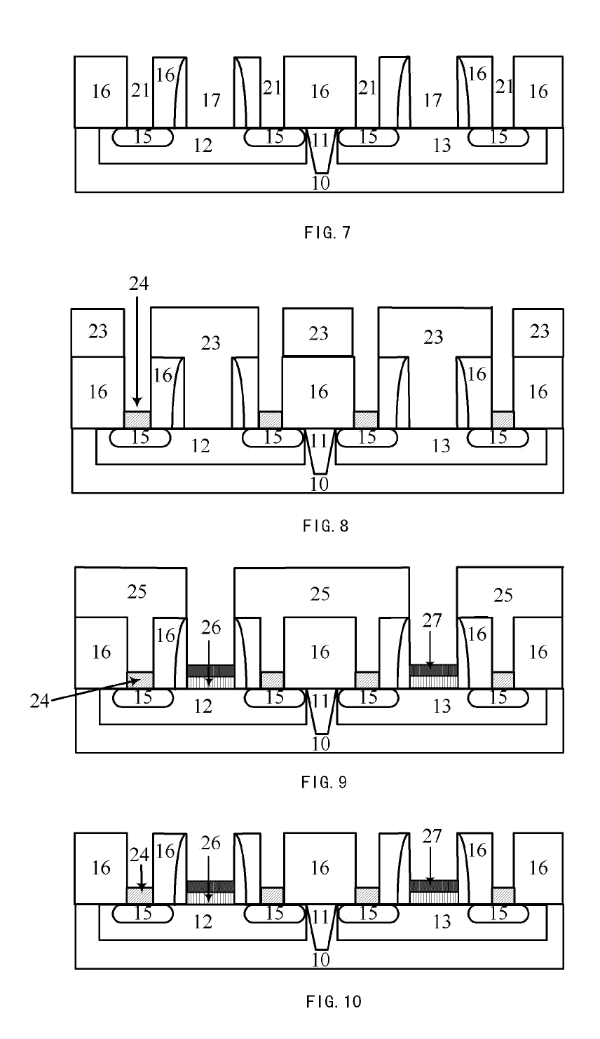

Thereafter, referring to FIG. 7, photo resist 20, hard mask 19, and filling material 18 are removed to expose the source/drain contact holes 21 and the gate trenches 17. The photo resist pattern 20 can be removed by means of O₂ plasma burning or wet etching. The hard mask 19 of LTO can be removed by using a HF-based etching solution. The filling material 18 can be removed by using organic solvent. After washing and drying the wafer, the gate trenches 17 and the contact holes 21 are exposed to deposit metal material.

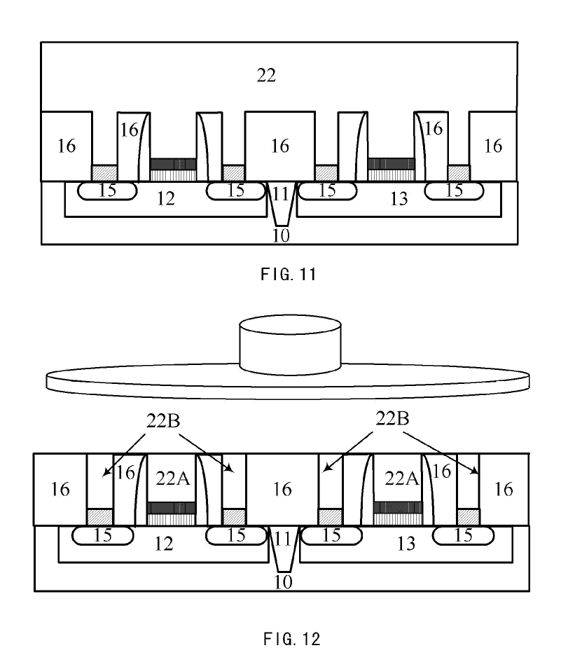

Then, metal is filled into the gate trenches 17 and the contact holes 21 to form gate and source/drain contacts, as shown in FIG. 11. However, preferably, in a variant embodiment of the present invention, the steps illustrated in FIGS. 8-10 may be inserted between the step illustrated in FIG. 7 and the step illustrate in FIG. 11 to reduce source/drain series resistance and increase dielectric constant of the gate dielectric layer, thereby improving device performance.

Specifically, referring to FIG. 8, photo resist is coated again on the surface of the wafer, filling fully the exposed gate trenches 17 and the contact holes 21 and is exposed and developed through a contact hole reticle to form a photo resist pattern 23 to expose the contact holes 21, but other parts including the gate trenches 17 are protected by the photo resist. Then metal precursors such as Ni, Pt, Co or the alloy thereof are respectively deposited by a PVD process such as sputtering (preferably, magnetron sputtering), with a thickness of, for example, about 300 Å. Then, photo resist in the trenches 17 and other parts is removed by organic degumming agent, which may be, for example, N-methylpyrroline (NMP), and the wafer is dried. After drying, annealing process is performed such that the precursors like Ni/Pt/Co etc. react with Si to produce electrically conductive silicide 24 to form Ohmic contact with metal plugs to be formed at a next step, thereby decreasing the contact resistance. The annealing process may be finished at a single step, for example, for 30 seconds at 400° C.

Furthermore, referring to FIG. 9, after the conductive silicide 24 is formed; photo resist is coated again on the surface of the wafer to fill fully the gate trenches 17 and the contact holes 21, and is exposed and developed through a reticle for gate trenches 17 to form a photo resist pattern 25. And hence the gate trenches are exposed, but other parts including the contact holes are protected by the photo resist, as shown in FIG. 9.

According to requirement of gate last process, the gate dielectric layer 26 comprising silicon oxide, silicon oxynitride, or a high-k material and metal gates 27 for adjusting work function are deposited by a furnace tube, ALD, or PVD process, respectively. The high-k material may be, for example, HfO₂ or HfSiON, and the material for the metal gate may be, for example, Ti, Ta, TiN or TaN and so on.

After depositing various dielectric films, the photo resist in the holes and other parts is removed by organic degumming agent, which may be, for example, NMP, and the wafer is dried, as shown in FIG. 10. At this time the gate trenches 17 and the source/drain contact holes 21 are exposed again, and the gate dielectric layer 26, metal gates 27 and silicide 24 are respectively formed therein, to thereby further improve device performance. It should be noted that the process steps as illustrated in FIGS. 8 and 9 are not necessarily performed at the same time, that is, forming either metal silicide 24 or the gate dielectric layer 26/metal gates 27, or forming them together, the principles for improving device performance are not the same.

Then, referring to FIG. 11 again, metal filling is performed. The gate trenches 17 and the contact holes 21 are filled with the same material to form metal gate contacts and metal source/drain contacts, respectively. Specifically, before deposition, an adhesive layer and/or a support layer (not shown) made of, for example, Ti, Ta (or TiN, TaN), is formed for the gate trenches 17 and the contact holes 21 by an ionized metal plasma deposition (IMP) technology. Then a barrier layer (not shown) is formed by a CVD process. The material for the barrier layer may be, for example, nitride which corresponds to the adhesive layer and/or support layer, that, comprises TiN, TaN (or Ti, Ta, that is, one of the support layer and the barrier layer is metal, and the other is the corresponding nitride). At last, a metal layer 22 is deposited into the gate trenches and the contact holes simultaneously by a CVD process with the same material. The metal layer 22 may be made of a material including W, Al, Cu, Ti, Ta and the combination thereof. Wherein, the adhesive layer and/or support layer may have a thickness of about 50-200 Å, preferably 100 Å. The barrier layer may have a thickness of about 20-100 Å, preferably 50 Å, and the metal layer 22 may have a thickness of about 1000-5000 Å, preferably 2500 Å.

At last, referring to FIG. 12, a CMP process is performed to the wafer, removing excess metal layer 22 and barrier layer above the gate electrodes and the contact holes, to finally obtain gate electrode wires 22A and source/drain contact wires 22B of the same material.

In accordance with the method for manufacturing gate electrodes and contact wires simultaneously in a gate last process of the present invention, the gate electrode wires can be made of the same metal material as the contact holes. For example, the filling metal is W. And hence the metal gate electrode wires and the W plug wires can be finished at a single CMP process. Such a design has the advantages of simplifying complexity of process integration on one hand and greatly strengthening control of defects by CMP process on the other hand, thereby avoiding the defects like erosion and dishing which may occur due to the difference of the metal materials.

Although the present invention is described with reference to one or more illustrative embodiments, it may be appreciated by those skilled in the art that various appropriate variations and equivalent modes may be made to the structure of the device without departing from the scope of the present invention. Furthermore, many modifications that may be applicable to specific situations or materials can be made from the teachings disclosed above without departing from the scope of the present invention.

Therefore, the object of the present invention is not to define the specific embodiments disclosed as the preferred embodiments for implementing the present invention, the disclosed device structure and the manufacturing method will include all embodiments falling within the scope of the present invention.

What is claimed is:

1. A method for manufacturing a gate electrode and a contact wire in a gate last process, comprising the steps of:
forming a gate trench in an inter layer dielectric layer on a substrate;
forming a filling layer in the gate trench and on the inter layer dielectric layer;
etching the filling layer and the inter layer dielectric layer to expose the substrate, to thereby form a source/drain contact hole;
removing the filling layer to expose the gate trench and the source/drain contact hole;
forming metal silicide in the source/drain contact hole;
depositing a gate dielectric layer and a metal gate in the gate trench;
filling metal in the gate trench and the source/drain contact hole; and
planarizing the filled metal.

2. The method according to claim 1, wherein the step of forming a gate trench comprises forming a dummy gate on the substrate, forming spacers around the dummy gate, forming an inter layer dielectric layer on the dummy gate and the spacers, CMP planarizing the inter layer dielectric layer to expose the dummy gate and removing the dummy gate.

3. The method according to claim 1, wherein further comprising forming a hard mask layer on the filling layer after the filling layer is formed.

4. The method according to claim 3, wherein the hard mask layer is a low temperature oxide.

5. The method according to claim 1, wherein the filling layer has a thickness greater than the depth of the gate trench.

6. The method according to claim 5, wherein the filling layer is formed by spinning a plurality of times to avoid voids.

7. The method according to claim 1, wherein the filling layer is made of a material with mobility and etching rate similar to that of the inter layer dielectric layer.

8. The method according to claim 7, wherein the filling layer is an anti-reflective coating.

9. The method according to claim 1, wherein the step of filling metal comprises filling an adhesive layer, a barrier layer, and a metal layer, in turn.

10. The method according to claim 9, wherein the adhesive layer comprising Ti, Ta, or TiN, TaN, the barrier layer comprising TiN, TaN or Ti, Ta, and the metal layer comprising W, Al, Cu, Ti, Ta and the combinations thereof.

11. The method according to claim 1, wherein the step of forming the metal silicide comprises: forming a photo resist pattern to expose the source/drain contact hole only, depositing a metal precursor in the source/drain contact hole, annealing to cause the metal precursor to react with silicon in the substrate to produce the metal silicide, and removing the photo resist pattern.

12. The method according to claim 11, wherein the metal precursor comprising Ni, Pt, Co and the alloy thereof.

13. The method according to claim 11, wherein annealing is performed for 30 seconds at 400° C.

14. The method according to claim 1, wherein the gate dialectic layer comprising silicon oxide, silicon oxynitride, or a high-k material, and the metal gate comprising Ti, Ta, TiN, or TaN.
